(19) United States
(12) Patent Application Publication
(10) Pub. No.: US 2005/0085062 A1
(43) Pub. Date: Apr. 21, 2005

(54) Processes and tools for forming lead-free alloy solder precursors

(75) Inventor: Bioh Kim, Kalispell, MT (US)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: Semitool, Inc.

(21) Appl. No.: 10/687,112

(22) Filed: Oct. 15, 2003

(51) Int. Cl. H01L 21/44

(52) U.S. Cl. 438/614

(57) ABSTRACT

Precursors for lead free alloy solder bumps are formed through selective deposition of at least two conductive layers. The conductive layers may include tin, silver, copper, gold, or bismuth. The conductive layers can also include alloys of the foregoing components. The precursor of the alloy solder bumps is re-flowed to form alloyed solder bumps.

### FIELD OF THE INVENTION

The present invention relates to microelectronic devices, and more particularly, to features that serve as precursors of solder bumps used for microelectronic packaging.

### BACKGROUND OF THE INVENTION

Mounting is an important step in semiconductor related device manufacture. With microelectronic devices becoming constantly smaller, and with the increase of complexity of circuitry, flip chip technology is increasingly used instead of conventional mounting technology, such as wire bonding or tape automated bonding. Flip chip technology allows a ductile direct electrical interconnect between a microelectronic device and a carrier for the device.

Solder bumps are used in flip chip applications. Solder bumps have been produced using lead tin alloys; however, the toxicity of lead has resulted in the investigation of lead-free solder alloys. Tin-silver and tin-silver based alloys have been considered as alternatives to lead based alloys for solder bumps. Although it may be possible to effectively co-deposit tin and silver and tin-silver based alloys, bath maintenance, bath life, alloy composition control, and deposition rate may limit the effectiveness of forming tin-silver and tin-silver based alloys through co-deposition.

It is possible to deposit tin-silver based alloys using screen-printing technology. Screen-printing allows a low cost method for producing relatively large geometry solder bumps, but has limitations as the size and the pitch of the solder bumps decrease. As the density of patterns and the complexity of circuitry increases, the feasibility of using screen-printing to provide solder bumps decreases.

### SUMMARY OF THE INVENTION

The present invention provides processes and tools for producing features that serve as precursors of solder bumps. Such precursors, when heated to a re-flow temperature, form an alloyed solder bump. The processes and tools of the present invention are able to form such solder bump precursors free of lead using electrolytic deposition techniques.

Device manufacturers wishing to use flip chip technology as a packaging solution will find the processes and tools of the present invention useful in forming lead-free solder bumps that facilitate high density bonding and gang bonding along with suitable electrical performance, self-alignment, and reliability characteristics. By employing the processes and utilizing the tools of the present invention, device manufacturers can avoid the toxicity issues associated with lead-based solders while taking advantage of the ability of the present invention to control the composition of the solder alloy and deposit the constituents of the solder alloy at an acceptable deposition rate. Additionally, the baths from which the components of the solder alloy precursor are deposited are simple to maintain and are relatively stable. Each of the above features of the present invention will contribute to the device manufacturer's ability to cost effectively produce solder bumps.

In one embodiment, a precursor of a solder alloy is formed on a microelectronic workpiece by first forming a diffusion barrier layer (e.g., copper or nickel stud) on a surface of the microelectronic workpiece. The diffusion barrier layer inhibits diffusion of materials on one side of the diffusion barrier layer into materials that are on the other side of the diffusion barrier layer, and protects underlying seed layer from being consumed when the materials around the diffusion barrier layer are heated to a re-flow temperature. Thereafter, a lead-free first conductive layer is formed over the diffusion barrier layer so that the diffusion barrier layer is located between the first conductive layer and the surface of the microelectronic pieces. A second lead-free conductive layer is then formed over the first conductive layer so that the first conductive layer is located between the second conductive layer and the diffusion barrier layer. The first and the second conductive layers are formed from different materials, for example, the first conductive layer can be silver and the second conductive layer can be tin.

In certain embodiments, additional lead-free conductive layers can be formed over the first and second conductive layers. In addition, in certain embodiments of the present invention, a diffusion barrier layer is not employed.

In accordance with the present invention, the various conductive layers can comprise a single conductive material or the conductive layer can comprise an alloy of at least two conductive materials. For example, a conductive layer may comprise an alloy of tin, silver, copper, gold, or bismuth.

Formation of the solder alloy precursors can be achieved in a tool that comprises one or more stations for carrying out the various functions described above.

The process and tools of the present invention produce precursors of lead-free alloy solder bumps useful in flip chip packaging solutions. The processes and tools provide an alternative to screen-printing technology and solder bump formation processes that attempt to directly co-deposit tin-silver alloy solder bumps.

### BRIEF DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIGS. 1A-1H are cross-sectional views illustrating one embodiment of a process for forming precursors of alloy solder bumps, and ultimately, solder bumps for microelectronic devices in accordance with the present invention;

FIG. 2 is a process flow chart of the steps for forming a precursors of alloy solder bumps in accordance with a first embodiment of the present invention;

FIG. 3 is a process flow chart of the steps for forming precursors of alloy solder bumps in accordance with a second embodiment of the present invention;

FIG. 4 is a process flow chart of the steps for forming precursors of alloy solder bumps in accordance with a third embodiment of the present invention; and

FIG. 5 is a schematic top plan view of a tool formed in accordance with the present invention for carrying out processes of the present invention.

### DETAILED DESCRIPTION OF PREFERRED EMBODIMENTS

The present invention is now described more fully with reference to the accompanying drawings, in which preferred embodiments of the invention are shown. The present invention, however, may be embodied in many different forms and should not be construed as limited to the embodiments set forth herein. Rather, the embodiments illustrated in the drawings noted above and described below are provided so that the description will be thorough and complete and will convey the scope of the present invention to those skilled in the art. For example, while the present invention is described below with respect to particular arrangements of conductive materials, the present invention is not limited to any one specific arrangement and the present invention may be embodied in many different arrangements of the various conductive layers used to form a solder alloy precursor. In the figures, the thickness of the various layers and regions have been exaggerated for clarity and are not relative in scope. It should be understood that when an element, such as a layer, surface, or substrate is referred to as being over another element, it can be directly on the other element or there may be intervening elements which may also be present whether illustrated or not.

As used throughout the specification, the term “plating” refers to electrolytic deposition, i.e., electroplating, unless the context clearly indicates otherwise. The term “feature” refers to a structure on a substrate. The term “precursor” refers to features that may be reflowed to form an alloy solder bump.

As used herein, the term “microelectronic workpiece” or “workpiece” is not limited to semiconductor wafers, but rather, refers to workpieces having generally parallel planar first and second surfaces that are relatively thin, including semiconductor wafers, ceramic workpieces, and other workpieces upon which microelectronic circuits or components, including submicron features, data storage elements or layers, and/or micro-mechanical elements are formed.

As used herein, the term “substitutional reduction” refers to the spontaneous deposition of noble metal ions, such as silver ions, onto a material having a lower reduction potential, such as tin due to the reduction potential difference.

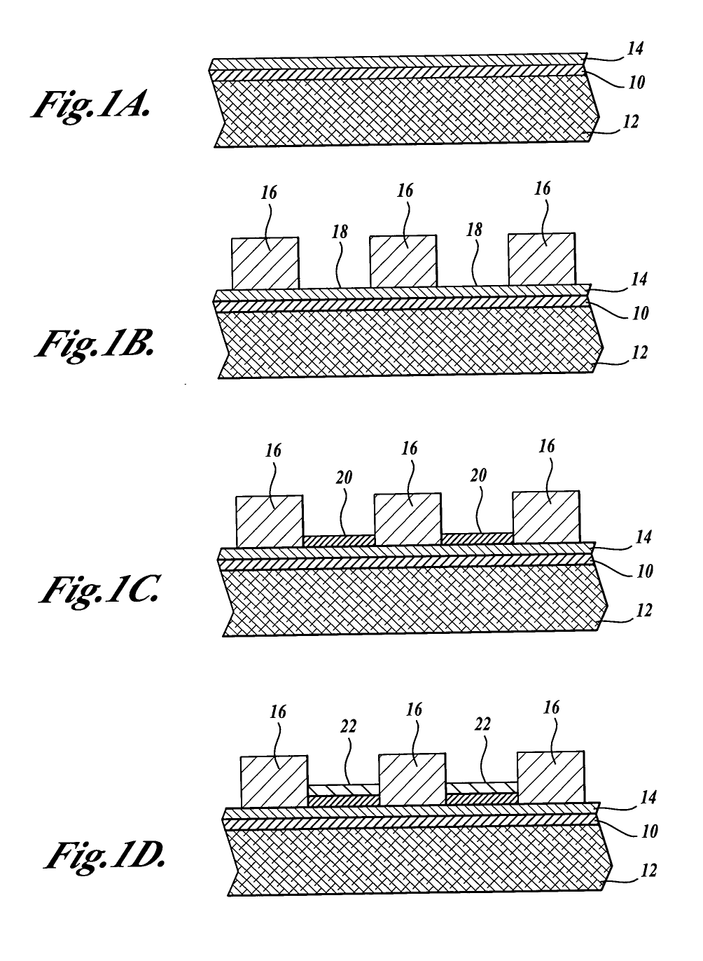

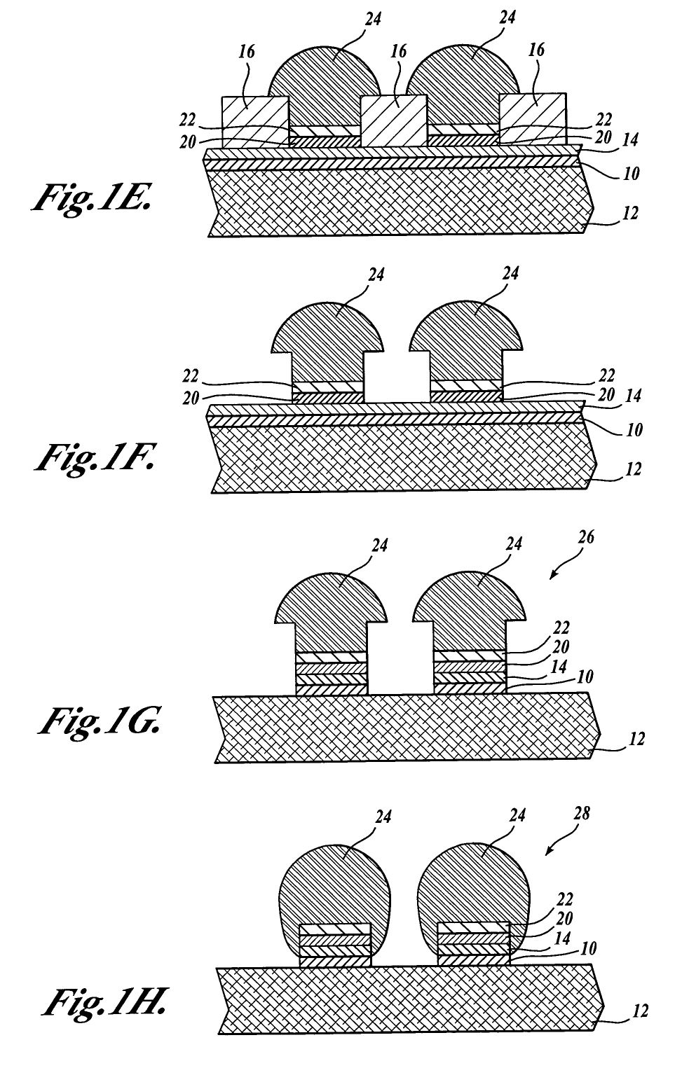

A method of forming a precursor for an alloy solder bump will now be described with reference to FIGS. 1A-1H. Referring to FIG. 1A, under bump metallurgy (UBM) comprising a barrier layer 10 and a seed layer 14 on a substrate 12, e.g., a silicon wafer is provided. The under bump barrier layer 10 separates substrate 12 from a second under bump metallurgy layer 14. In the illustrated embodiment, under bump metallurgy layer 14 is a seed layer formed of a conductive material, such as copper. Under bump metallurgy layer 10 serves as a barrier layer and inhibits diffusion of the seed layer material into the underlying metal interconnects within the substrate 12 which are not illustrated in figures. UBM layer 10 also serves to provide adhesion of UBM layer 14 to underlying materials. Barrier layer 10 can be formed from known materials, such as titanium, chromium, or titanium tungsten. UBM layers 10 and 14 can be formed using conventional techniques, such as sputtering or any other well known techniques. Accordingly, further description of the formation of the UBM layers is not provided herein.

Referring to FIG. 1B, a photoresist 16 is coated over the second UBM layer 14 and then patterned using conventional techniques to form a patterned mask over the second UBM layer 14. Patterned photoresist 16 defines exposed portions 18 of the second UBM layer 14.

Referring to FIG. 1C, in accordance with this embodiment of the present invention, an additional diffusion barrier layer 20 is formed on the exposed portions 18 of the second UBM layer 14. The second diffusion barrier layer 20 comprises a conductive material, such as copper or nickel, and may be deposited by conventional electrochemical deposition techniques, such as electrolytic or electroless processes. The diffusion barrier layer 20 protects underlying seed layer 14 from being consumed during a subsequent reflow of the deposited precursor. Consumption of the metal comprising seed layer 14 occurs when intermetallic compounds are formed between the metal of the seed layer and other metals in the solder precursors of the present invention. In other embodiments, it may be unnecessary to deposit an additional diffusion barrier layer 20, for example, when consumption of the metal of the seed layer is not a concern. Both copper and nickel function to isolate seed layer 14 from the conductive materials of the conductive layers 22 and 24 described below in more detail. The thickness to which the diffusion barrier layer 20 is deposited is chosen so that during reflow processes (including multiple reflow processes), formation of intermetallic compounds between the material of the diffusion barrier layer 20 and the overlying conductive layers does not result in significant portions of the underlying seed layer forming intermetallic compounds with the materials of the overlying conductive layers 22 and 24. It should be understood that during the reflow, small amounts of the seed layer 14 may form intermetallic compounds with the solder components through diffusion; however, the presence of the second diffusion barrier layer serves to minimize such diffusion. Diffusion of the seed layer 18 into the conductive materials making up the solder precursor during the reflow is undesirable because it may lead to reduced adhesion, poor mechanical strength, and degradation of the quality of electrical contact between the seed layer and underlying conductive features such as electrical pads.

Referring to FIG. 1D, a lead-free conductive layer 22 is formed over the second diffusion barrier layer 20 within the openings defined in patterned photoresist 16. In this embodiment, conductive layer 22 comprises silver, although as described below in more detail, the present invention is not necessarily limited to conductive layer 22 comprising silver. Conductive layer 22 can be formed using conventional electrolytic techniques that are well known to one skilled in the art, and therefore further description of such electrolytic techniques is not provided herein.

Referring to FIG. 1E, a second lead-free conductive layer 24 is deposited over the first conductive layer 22 within the opening defined within patterned photoresist 16. In the illustrated embodiment, forming of conductive layer 24 is carried out such that the material of conductive layer 24 is deposited above the surface of patterned photoresist 16 to form a dome-shaped feature above the photoresist. In the illustrated embodiment, conductive layer 24 is formed from tin, although as described below in more detail, the present invention is not so limited. Conductive layer 24 can be formed using conventional electrolytic techniques that are well known to one skilled in the art, and therefore further description of such electrolytic techniques is not provided herein.

Referring to FIG. 1F, patterned photoresist 16 is removed exposing those portions of UBM seed layer 14 not covered by the second diffusion barrier layer 20. Photoresist layer 16 can be removed by conventional techniques well known to those skilled in the art, and therefore further details regarding such techniques are not necessary herein.

Referring to FIG. 1G, those portions of UBM barrier layer 10 and UBM seed layer 14 that are not underneath the second diffusion barrier layer 20 are removed using conventional techniques, such as acid etching. Techniques for etching portions of the UBM barrier layer 10 and UBM seed layer 14 that are not beneath the second diffusion barrier layer 20 are well known to those of skill in the art, and therefore further details regarding such techniques are not provided herein. The resulting structure resembles a mushroom and comprises a lead-free solder alloy precursor 26. The illustrated features are described as precursors because subsequent heating of such structures to a re-flow temperature causes the second conductive layer 24 to flow and envelop in part the underlying first conductive layer 22, second diffusion barrier layer 20, and UBM seed layer 14, where the UBM barrier layer 10 does not wet with the first 22 and the second conductive layers 24. The alloyed solder bump 28 is formed from the precursor by diffusion and reaction between the first conductive layer 22 and the second conductive layer 24. In the illustrative embodiment, the alloyed solder bump is formed from the precursor by diffusion of the silver of the first conductive layer 22 into the tin, which exists in a liquid state. During the re-flow, the alloy composition is formed by the material migration that occurs at the interface between the liquid tin and the silver in the solid state. The composition of the resulting solder alloy is a function of the re-flow temperature, time, and the thickness of the silver and tin layers. These parameters provide a means for controlling the composition of the resulting solder alloy bump.

In order to facilitate the formation of the solder bump 28, the solder bump precursor 26 can be coated with flux.

The specific re-flow temperature will depend upon the compositions of the solder bump precursor 26. For the illustrated embodiment of tin and silver, re-flow may be performed at temperatures below 300° C., and more preferably, below about 260° C.

Referring to FIGS. 1A-1H and FIG. 3, the present invention includes processes that form conductive layers in addition to the first conductive layer 22 and the second conductive layer 24 in FIG. 1. For example, in FIG. 3, an alternative process sequence deposits a third conductive layer over the exposed portions 18 of the UBM. The present invention contemplates processes that deposit additional layers of conductive materials over the exposed portions of the UBM. For example, precursors of the present invention can include 3, 4, 5, 6, or more conductive layers. In the process sequence described in FIG. 3, the diffusion barrier layer 20 is omitted. Examples of alternative sequences of conductive layers include the following which lists specific metals from left to right, representing the order of conductive layers moving in a direction away from the underlying substrate. The slash marks (/) designate the interface between distinct conductive layers.
silver/tin/silver/tin
silver/copper/tin/silver/copper/tin
tin/silver/tin
tin/copper/silver/tin/copper/silver/tin

The foregoing are provided as examples of other sequences and combinations of conductive layers, but it is understood that the present invention is not limited to the foregoing sequences.

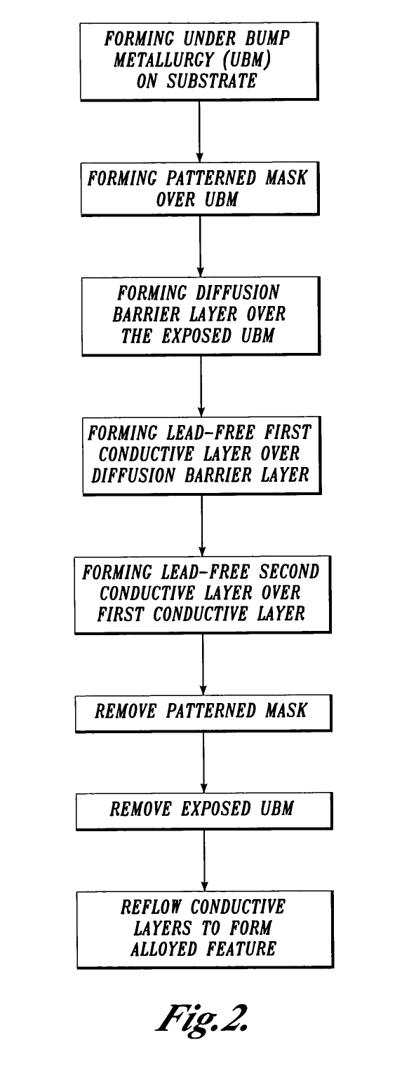

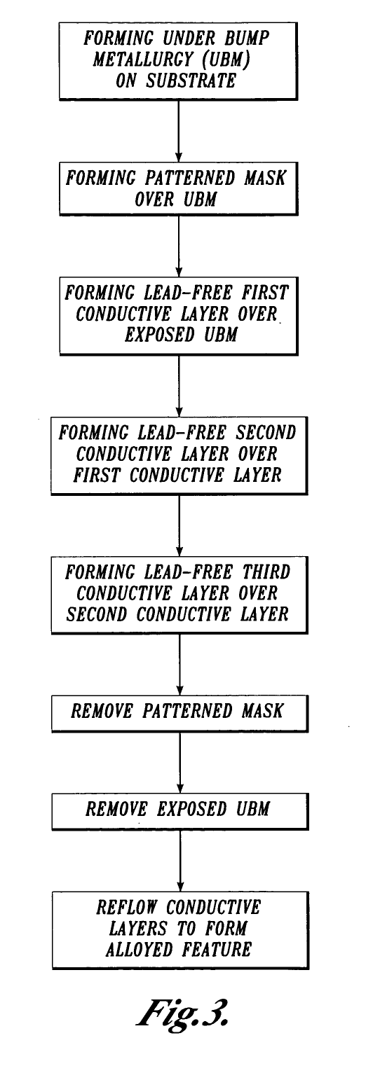

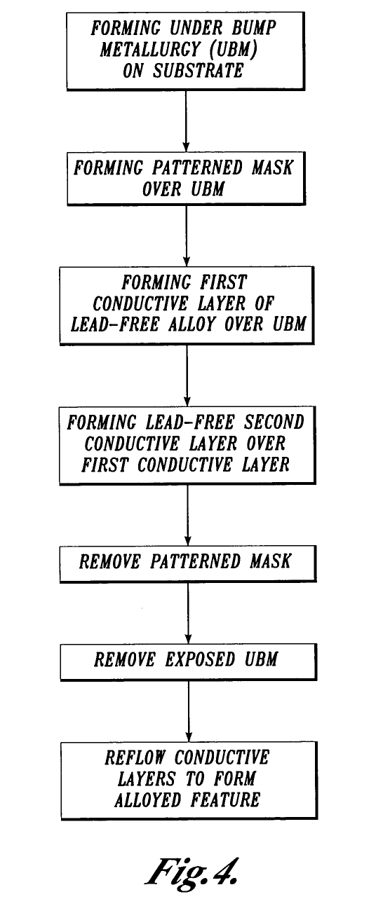

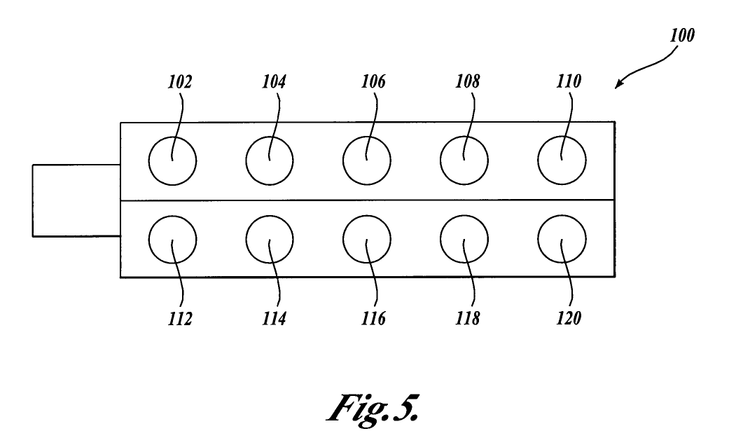

Referring to FIG. 4, in another embodiment, the process sequence described above with respect to FIG. 1A-1H and FIG. 2 is modified so that the first lead-free conductive layer 22 is formed as an alloy of at least two different conductive materials, such as tin, silver, copper, gold, and bismuth. In accordance with this embodiment, after the alloy of the first conductive layer is deposited, a second conductive layer 24 is formed over the first conductive layer 22. The resulting structure is then treated in a manner similar to that described with respect to FIG. 1E-1H to produce a solder bump precursor in accordance with the present invention. It should be understood that the alloy described as being deposited as the first conductive layer can be deposited as the second conductive layer. In addition, it should be understood that as described above with respect to FIG. 3, additional conductive layers comprising alloys or individual conductive materials can be used to form the solder bump precursor. Examples of alloys that are useful include tin-copper, tin-silver, tin-gold, tin-bismuth, and silver-copper. Examples of sequences of conductive layers wherein at least one of the layers is an alloy include the following where the materials of the various layers are set forth from left to right reflecting the arrangement of the layers moving away from the substrate. The slash marks (/) designate the interface between distinct conductive layers.
silver/tin-copper/silver/tin-copper
silver-copper/tin/silver-copper/tin
tin-copper/tin-silver/tin-copper/tin-silver/tin-copper
copper/tin/tin-silver/copper/tin/tin-silver
tin-copper/silver/tin-copper
tin-silver/copper/tin-silver
tin/silver-copper/tin

As described above, the various conductive layers comprising individual metals or metal alloys can be formed using electrolytic techniques. The conductive layers can also be formed by substitutional reduction. Substitutional reduction is useful when the metal to be deposited has a higher reduction potential than the metal onto which the first metal is to be deposited. For example, silver, copper, bismuth, and gold can be deposited by substitutional reduction onto a tin-containing conductive layer. Substitutional reduction can be used to form a solder bump precursor, which includes the following layers, listed in an order moving away from the underlying substrate. Again, the conductive layers are separated by slash marks (/).
tin/silver/tin/silver/tin (silver is substitutionally reduced)
tin-copper/silver/tin-copper/silver/tin-copper
   (silver is substitutionally reduced)
copper/tin/silver/copper/tin/silver/tin

The solder bump precursors can be re-flowed to produce alloy solder bumps comprising the preferred target compositions set forth in the table below.

SOLDER BUMP COMPOSITION (WT %)

| | | | | | Sn/Bi | |
|---|---|---|---|---|---|---|
| | Sn/Ag | Sn/Cu | Sn/Bi | Sn/Au | (High Sn) | SnAgCu |
| Tin (Sn) | 93.5-98.0 | 98.5-99.9 | 38-48 | 15-25 | 85-99 | 92.0-97.9 |
| Silver (Ag) | 2.0-6.5 | - | — | — | — | 2.0-6.5 |
| Copper (Cu) | — | 0.1-1.5 | — | — | — | 0.1-1.5 |
| Bismuth (Bi) | — | — | 52-62 | — | 1-15 | — |
| Gold (Au) | — | — | — | 75-85 | — | — |

The formation of solder alloy precursors in accordance with the present invention may be implemented in a wide range of tools. Integrated processing tools that incorporate one or more reactors capable of electrolytic deposition of conductive materials are particularly suitable for implementing the processes of the present invention and are available from Semitool, Inc., of Kalispell, Mont. Such tools are sold under the brand names Equinox® or LT-210®, Paragon®, and Raider™. Advantageously, the reactors employed in these tools rotate a workpiece during the electrolytic deposition process thereby enhancing the uniformity of the resulting deposited film. Integrated processing tools are also available from other manufacturers.

In addition to the electrolytic deposition reactors, such tools frequently include other ancillary processing chambers, such as, for example, pre-wetting chambers, rinsing chambers, etc., that are used to perform other processes associated with electrolytic deposition. Semiconductor wafers, as well as other microelectronic workpieces, are transferred between the various processing reactors, as well as between the processing reactors and input/output stations, by a robotic transfer mechanism. The robotic transfer mechanism, the electroplating reactors, and the plating recipes used, as well as other components of the tool, may all be under the control of one or more programmable processing units.

Referring to FIG. 5, a tool 100 formed in accordance with the present invention includes a plurality of workstations for carrying out pre-wet, spin/rinse/dry, and electrolytic deposition steps. The particular arrangement of the various workstations can vary; however, FIG. 5 illustrates an exemplary layout. In FIG. 5, workstations 102, 104, and 112 are spin/rinse/dry chambers capable of applying acid, base, DI water, or other solutions to a workpiece surface. Chambers 102, 104, and 112 can also be used to pretreat the workpieces, for example, by pre-wetting them prior to further processing. Workstations 114 and 116 are reactors for electrolytically depositing the various conductive layers described above. For example, workstations 114 and 116 can be configured to electrolytically deposit copper. Workstations 106, 108, and 110 can be configured to electrolytically deposit tin. Workstations 118 and 120 can be configured to electrolytically deposit silver. In an exemplary processing sequence, a workpiece is pre-wetted at one of stations 102, 104, or 112. The workpiece is then transferred to one of workstations 114 or 116 where copper deposition is carried out followed by a return to one of the spin/rinse/dry workstations 102, 104, or 112 where it is processed to prepare it for the next deposition step. The workpiece is then delivered from the spin/rinse/dry workstation to one of the electrolytic deposition workstations 106, 108, or 110 where tin is deposited. The workpiece is delivered from the tin deposition station to one of the spin/rinse/dry workstations to prepare it for the next deposition step. The workpiece is then delivered to one of workstations 118 or 120 where electrolytic deposition of silver is carried out followed by a return to a spin/rinse/dry workstation to prepare it for the next deposition step. Thereafter, the workpiece is delivered to one of workstations 106, 108, or 110 where an additional layer of tin is deposited followed by a return to one of the spin/rinse/dry workstations for rinsing and drying.

The dried workpiece with the deposited copper/tin/silver/tin conductive layers can then be transferred to another tool where the removal of photoresist and UBM layers is carried out prior to processing the workpiece to reflow the conductive layers to form a solder bump.

It should be understood that there are numerous configurations of various workstations that can be employed depending upon the particular configuration of conductive layers that are to be deposited as described above. The foregoing is provided as an example of a tool configuration useful for carrying out a process in accordance with the present invention.

While the preferred embodiments of the invention have been illustrated and described, it will be appreciated that various changes can be made therein without departing from the spirit and scope of the invention.

1. A process of forming a solder alloy precursor on a microelectronic workpiece that includes a patterned mask over a conductive under bump metallurgy, the patterned mask exposing portions of the conductive under bump metallurgy, the process comprising:
forming a diffusion barrier layer on the exposed portions of the conductive under bump metallurgy;
forming a lead-free first conductive layer over the diffusion barrier layer, the diffusion barrier layer located between the first conductive layer and the under bump metallurgy; and
forming a lead-free second conductive layer over the first conductive layer, the first conductive layer located between the second conductive layer and the diffusion barrier layer, wherein the second conductive layer has a different composition than the first conductive layer.

2. The process of claim 1 wherein the diffusion barrier layer comprises copper or nickel.

3. The process of claim 1, wherein the first conductive layer comprises tin, silver, copper, gold, or bismuth.

4. The process of claim 3, wherein the first conductive layer comprises tin or silver.

5. The process of claim 1, wherein the second conductive layer comprises tin, silver, copper, gold, or bismuth.

6. The process of claim 5, wherein the second conductive layer comprises tin or silver.

7. The method of claim 1 further comprising forming at least one additional conductive layer over the diffusion barrier layer.

8. The method of claim 7, wherein the at least one additional conductive layer comprises tin, silver, copper, gold, or bismuth.

9. The method of claim 1, wherein the diffusion barrier layer is formed by electrolytic deposition.

10. The method of claim 1, wherein either the first or the second conductive layer is free of tin and silver.

11. A process of forming a solder alloy precursor on a microelectronic workpiece comprising:
forming a lead-free first conductive layer on a surface of the microelectronic workpiece;
forming a lead-free second conductive layer over the first conductive layer, the first conductive layer located between the second conductive layer and the surface of the microelectronic workpiece, wherein the second conductive layer has a different composition than the first conductive layer; and
forming a lead-free third conductive layer over the second conductive layer, the second conductive layer located between the third conductive layer and the first conductive layer, wherein the third conductive layer has a different composition than the second conductive layer.

12. The method of claim 11, wherein the first, second, and third conductive layers comprise tin, silver, copper, gold, or bismuth.

13. The method of claim 11, wherein the first, second, and third conductive layers comprise tin, silver, or copper.

14. The process of claim 11, further comprising the step of forming at least one additional conductive layer.

15. The process of claim 14, wherein the at least one additional conductive layer comprises tin, silver, copper, gold, or bismuth.

16. A process of forming a solder alloy precursor on a microelectronic workpiece comprising:
forming a lead-free first conductive layer on a surface of the microelectronic workpiece; and
forming a lead-free second conductive layer over the first conductive layer, the first conductive layer located between the second conductive layer and the surface of the microelectronic workpiece, wherein the second conductive layer has a different composition than the first conductive layer, at least one of the first and second conductive layers comprising an alloy of at least two conductive materials.

17. The process of claim 16, wherein the first and second conductive layers comprise tin, silver, copper, gold, or bismuth.

18. The method of claim 16, wherein the at least two conductive materials are selected from tin, silver, copper, gold, and bismuth.

19. The method of claim 16, further comprising forming at least one additional conductive layer over the surface of the microelectronic workpiece.

20. The method of claim 19, wherein the additional conductive layer comprises tin, silver, copper, gold, or bismuth.

21. A process of forming a solder alloy precursor on a microelectronic workpiece comprising:
forming a lead-free first conductive layer on a surface of the microelectronic workpiece; and
forming a lead-free second conductive layer over the first conductive layer, the first conductive layer located between the second conductive layer and the surface of the microelectronic workpiece, wherein the second conductive layer has a different composition than the first conductive layer, wherein the second conductive layer is formed by substitutional reduction.

22. The method of claim 21, wherein the first and second conductive layers comprise tin, silver, copper, gold, or bismuth.

23. The method of claim 21, wherein the first and second conductive layers comprise tin or silver.

24. The method of claim 21 further comprising the step of forming at least one additional conductive layer over the microelectronic workpiece.

25. The process of claim 24, wherein the at least one additional conductive layer comprises tin, silver, copper, gold, or bismuth.

26. The method of claim 21, wherein the second layer comprises silver, copper, gold, or bismuth.

27. A tool for forming a solder alloy precursor on a microelectronic workpiece that includes a patterned mask over a conductive under bump metallurgy, the patterned mask exposing portions of the conductive under bump metallurgy, said tool comprising one or more stations for:
forming a diffusion barrier layer on the exposed portions of the conductive under bump metallurgy;
forming a lead-free first conductive layer over the diffusion barrier layer, the diffusion barrier layer located between the first conductive layer and the under bump metallurgy; and
forming a lead-free second conductive layer over the first conductive layer, the first conductive layer located between the second conductive layer and the diffusion barrier layer, the second conductive layer having a different composition than the first conductive layer.

28. The tool of claim 27, wherein the station for forming a diffusion barrier layer comprises a reactor for electrolytically depositing the diffusion barrier layer.

29. The tool of claim 27 further comprising a source of copper or nickel.

30. The tool of claim 27, wherein the station for forming the first conductive layer comprises a reactor for electrolytically depositing the first conductive layer.

31. The tool of claim 30 further comprising a source of tin, silver, copper, gold, or bismuth.

32. The tool of claim 27, wherein the station for forming the second conductive layer comprises a reactor for electrolytically depositing the second conductive layer.

33. The tool of claim 32 further comprising a source of tin, silver, copper, gold, or bismuth.

34. The tool of claim 27, further comprising a station for rinsing the workpiece.

35. The tool of claim 27, further comprising a station for pre-wetting the workpiece.

36. A tool for forming a solder alloy precursor on the surface of a microelectronic workpiece, including conductive under bump metallurgy, said tool comprising one or more stations for:
forming a lead-free first conductive layer over the conductive under bump metallurgy;
depositing a lead-free second conductive layer over the first conductive layer, the first conductive layer located between the second conductive layer and the conductive under bump metallurgy, wherein the second conductive layer has a different composition than the first conductive layer; and
forming a lead-free third conductive layer over the second conductive layer, the second conductive layer located between the third conductive layer and the first conductive layer, wherein the third conductive layer has a different composition than the second conductive layer.

37. A tool for forming a solder alloy precursor on a microelectronic workpiece including conductive under bump metallurgy, said tool comprising one or more stations for:
forming a lead-free first conductive layer over the conductive under bump metallurgy; and
forming a lead-free second conductive layer over the first conductive layer, the first conductive layer located between the second conductive layer and the conductive under bump metallurgy, wherein the second conductive layer has a different composition than the first conductive layer, at least one of the conductive layers being an alloy comprising at least two conductive materials.

38. The tool of claim 37, wherein either the station for forming the first conductive layer or the station for forming the second conductive layer includes a source of at least two metals selected from tin, silver, copper, gold, or bismuth.

39. A tool for forming a solder alloy precursor on the surface of a microelectronic workpiece including conductive under bump metallurgy, said tool comprising one or more stations for:
forming a lead-free first conductive layer over the conductive under bump metallurgy;
forming a lead-free second conductive layer over the first conductive layer, the first conductive layer located between the second conductive layer and the conductive under bump metallurgy, wherein the second conductive layer has a different composition than the first conductive layer and is formed by substitutional reduction.

40. A tool for forming a solder alloy precursor on a microelectronic workpiece that includes a patterned mask over a conductive under bump metallurgy, the patterned mask exposing portions of the conductive under bump metallurgy, the tool comprising:
a diffusion barrier layer deposition reactor including a source of copper or nickel,
a first conductive layer deposition reactor including a source of a first conductive material;
a second conductive layer deposition reactor including a source of a second conductive material different from the first conductive material.

41. A tool for forming a solder alloy precursor on a microelectronic workpiece that includes a patterned mask over a conductive under bump metallurgy, the patterned mask exposing portions of the conductive under bump metallurgy, the tool comprising:
a first conductive layer deposition reactor including a source of a first conductive material;
a second conductive layer deposition reactor including a source of a second conductive material different from the first conductive material;
a third conductive layer deposition reactor including a source of a third conductive material different from the second conductive material.
